(19) United States
(12) Patent Application Publication
(10) Pub. No.: US 2020/0273715 A1
(43) Pub. Date: Aug. 27, 2020

(54) METHOD OF SMOOTHING AND PLANARIZING OF ALTIC SURFACES

(71) Applicant: TEL Manufacturing and Engineering of America, Inc., Chaska, MN (US)

(72) Inventors: Luis Fernandez, Billerica, MA (US); Martin Tabat, Billerica, MA (US)

(21) Appl. No.: 16/797,726

(22) Filed: Feb. 21, 2020

Related U.S. Application Data
(60) Provisional application No. 62/809,036, filed on Feb. 22, 2019.

(51) Int. Cl. H01L 21/321; H01L 21/265; H01L 21/304; H01L 21/67

(52) U.S. Cl. CPC H01L 21/3212; H01L 21/67219; H01L 21/304; H01L 21/26566

(57) ABSTRACT

Techniques herein provide effective smoothing and planarization of various surfaces. Techniques include using multiple particle beams to correct different aspects of a given workpiece. A workpiece needing correction from scratches and roughness is treated with a first particle beam that reduces scratches on a working surface of the workpiece using an inert beam. The workpiece is also treated with a second particle beam that is chemically reactive and reduces step-height values across the working surface of the workpiece, thereby producing a surface with reduced scratches and roughness.

### CROSS REFERENCE TO RELATED APPLICATIONS

The present application claims the benefit of U.S. Provisional Patent Application No. 62/809,036, filed on Feb. 22, 2019, entitled “Method of Smoothing and Planarizing of AlTiC Surfaces,” which is incorporated herein by reference in its entirety.

### BACKGROUND OF THE INVENTION

This disclosure relates material processing, semiconductor fabrication, and integrated circuit manufacturing. More specifically, but not exclusively, this disclosure relates to the location specific processing of various substrates.

With the advancement of substrate size and feature scale in semiconductor device manufacturing from one technology node to the next, as well as the increasing complexity of devices transitioning from planar to non-planar, the need for advanced precision control of feature attributes across large diameter substrates is rapidly escalating. Current methodologies, including beam processing systems as well as non-beam processing systems, such as spatially-controlled plasma and non-plasma processing systems, are contemplated for advanced corrective processing schemes.

As an example, location specific processing by gas cluster ion beam (GCIB) is a highly precise method, which, among other capabilities, enables advanced process control of feature attribute uniformity (e.g., thickness uniformity). In a GCIB etching process, a GCIB system can have a high local etch rate in a focused beam, which combined with location specific processing (LSP) algorithms, enables high-precision correction of incoming or downstream thickness uniformity.

Clusters of gas molecules are formed by condensation that occurs during expansion of a high pressure gas mixture through a nozzle. A beam of these clusters is directed through an electron source, where the clusters are ionized by electron impact, then accelerated by up to 60 KV into the process chamber where a substrate (typically a wafer) is scanned through the beam.

Workpieces (substrates) are scanned with precisely controlled speed up to 150 cm/s, for example, which can be modulated at every point on the wafer using the processing algorithm to precisely control local treatment or etch rate based on a downloaded map or via an integrated metrology option.

### SUMMARY

Various different materials have their respective challenges for processing. One such material is aluminum titanium carbon (AlTiC). AlTiC is an alloy that is used for some electronic devices as a substrate and/or surface. Processing of such AlTiC surfaces can include chemical-mechanical polishing (CMP). Processing AlTiC surfaces via CMP can result in scratches and a non-planar topography (roughness). Thus part of correcting AlTiC surfaces involves removing scratches and normalizing high spots and low spots.

Techniques herein include a method for performing corrective processing of a substrate. A workpiece is positioned in a beam apparatus. The beam apparatus is configured to treat a workpiece using a particle beam. The beam apparatus includes a vacuum chamber having a beam line for forming a particle beam and treating the workpiece with the particle beam. The beam apparatus also includes a scanner mechanism for translating the workpiece through the particle beam. The workpiece has a working surface to be corrected. A first particle beam is generated in the vacuum chamber. The first particle beam is a particle beam of inert particles. The workpiece is scanned through the first particle beam according to a first correction map for a first characteristic of a working surface of the workpiece. The first particle beam causes a modification of the first characteristic on the working surface of the workpiece. A second particle beam is generated in the vacuum chamber. The second particle beam is a particle beam of reactive particles. The workpiece is scanned through the second particle beam according to a second correction map for a second characteristic of the working surface of the workpiece. The second particle beam causes a modification of the first characteristic on the working surface of the workpiece.

Of course, the order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

Note that this summary section does not specify every embodiment and/or incrementally novel aspect of the present disclosure or claimed invention. Instead, this summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

A more complete appreciation of various embodiments of the invention and many of the attendant advantages thereof will become readily apparent with reference to the following detailed description considered in conjunction with the accompanying drawings. The drawings are not necessarily to scale, with emphasis instead being placed upon illustrating the features, principles and concepts.

FIG. 1A is a magnified image of a substrate surface showing scratches.

FIG. 1B is a magnified image of a substrate surface showing roughness.

FIG. 1C is a graph measuring roughness of a substrate surface.

FIG. 1D is a magnified perspective view of a substrate surface showing roughness.

FIG. 2 is a magnified image of a substrate surface showing reduced scratches and reduced roughness according to embodiments herein.

FIG. 3 is a simplified schematic of a beam processing system.

FIG. 4 is a cross-sectional schematic diagram of a gas cluster ion beam (GCIB) processing system herein.

### DETAILED DESCRIPTION

Techniques herein provide effective smoothing and planarization of various surfaces. Techniques include using multiple particle beams to correct different aspects of a given workpiece. A workpiece needing correction from scratches and roughness is treated with a first particle beam that reduces scratches on a working surface of the workpiece using an inert beam. The workpiece is also treated with a second particle beam that is chemically reactive and reduces step-height values across the working surface of the workpiece, thereby producing a surface with reduced scratches and roughness.

Embodiments herein can be used for treating various non-homogeneous materials such as aluminum-titanium-carbon (AlTiC). Although homogeneous materials can typically be etched evenly across a given surface, etching non-homogeneous materials, however, is more challenging and typically results in differential etching to various degrees. For convenience in describing embodiments herein, example embodiments will focus on smoothing the working surface of an AlTiC substrate using gas cluster Ion beam (GCIB) treatments. Aluminum-titanium-carbon alloys are commonly used in the manufacture of hard disk drives. AlTiC surfaces, however, are not homogeneous. As discovered herein, AlTiC surfaces have distinct areas that exhibit differential etching characteristics. During the processing of AlTiC surfaces, a common processing step in the fabrication process is that of chemical-mechanical polishing (CMP). CMP uses a combination of chemical etching and abrasive polishing as a technique to planarize and smooth various surfaces. CMP treatment of AlTiC surfaces typically results in polishing scratches as well as some roughness. Local variations in the alloy (non-homogenous areas) result in more or less local polishing. This leaves a non-planar surface with z-height differences.

AlTiC surfaces perform better for hard disk drives with a very smooth and scratch-free surface condition. To provide such desired surface correction, techniques here include a multi-step GCIB smoothing process. In one embodiment, this multi-step process combines an inert beam (e.g. N₂) for scratch removal and smoothing, followed by a chemical etching beam (e.g. NF₃). The NF₃ beam preferentially etches one of the distinct areas faster than the other, reducing the step height difference between the distinct areas in the nonhomogeneous surface. As a result of the multi-step process, AlTiC surfaces accordingly treated are scratch-free, planarized and smooth.

In one embodiment, a starting surface of a substrate is scratched, having a random surface morphology. This working surface is composed of high areas referred to as “mesas,” and low areas referred to as “valleys.” These areas can have a different composition, as evidenced by differences in relative etching rates. Optionally, the surface of an incoming substrate can be measured or otherwise mapped to spatially identify areas for correction. Conventional metrology tools can be used to measure and map surface scratches and roughness. Mapping can be by substrate lot or by individual substrate. As mentioned, mapping is optional and not needed. The entire substrate surface can be treated the same way and yield reduced scratches and roughness.

A first GCIB treatment is executed on the surface. The surface is scanned through an inert (e.g. N₂ beam) particle beam according to surface morphology. This first GCIB treatment removes or lessens scratches, and the resulting surface morphology is less random, with clearer mesas and valleys present. This first particle beam treatment preferentially etches the valleys. A second GCIB treatment is executed on the surface. The surface is scanned through a reactive beam (e.g. NF₃ beam) of particles. The second particle beam preferentially etches the mesas as species from the particle beam react more with material from the mesas. A sufficient dose per location on the surface is executed to result in mesas being planar with valleys. By way of a non-limiting example, a given surface can have mesas to be reduced by 2 nm, 8 nm, or more. Accordingly, depending on average mesa heights or maximum mesa heights or measured/calculated height differentials to correct, a sufficient dose can be given to reduce z-height by 2 nm, 8 nm, 20 nm or more.

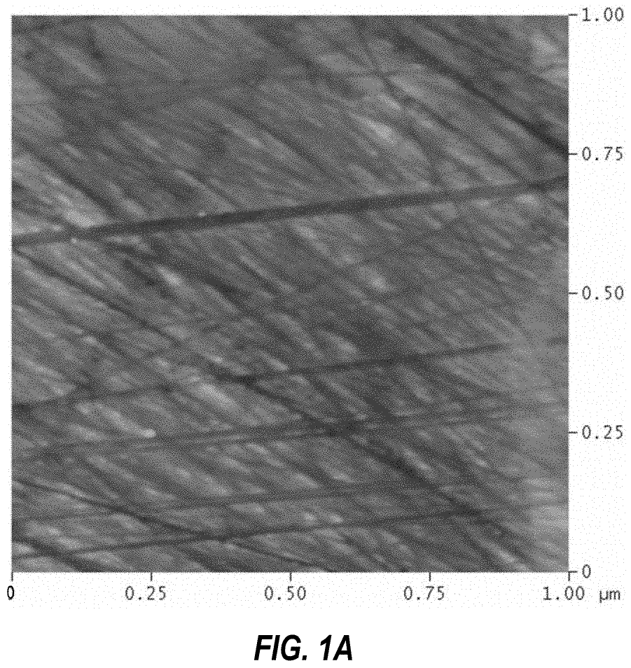

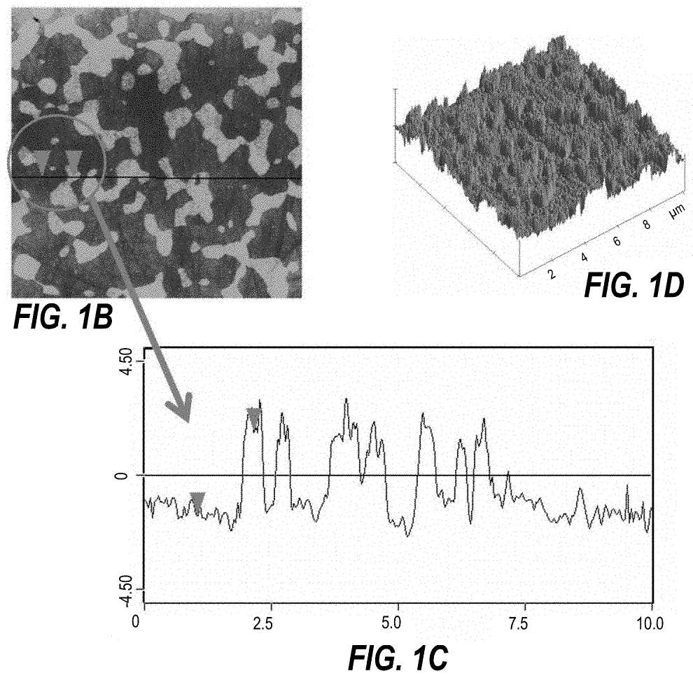

FIG. 1A is a magnified image of an AlTiC surface after CMP treatment. The surface is scanned with atomic force microscopy (AFM) at a 1 uM×1 uM resolution. Note that lines (micro-scratches) are easily observable.

FIG. 1B is another magnified image of an AlTiC surface after CMP treatment. This AFM scan is at 10 uM by 10 uM resolution. Note that mesas and valleys can be seen. FIG. 1D is a perspective view of this roughness. FIG. 1C is a graph showing a peak to valley vertical distance of about 3 nanometers for this particular substrate. Lighter areas are taller/higher than darker areas in this image.

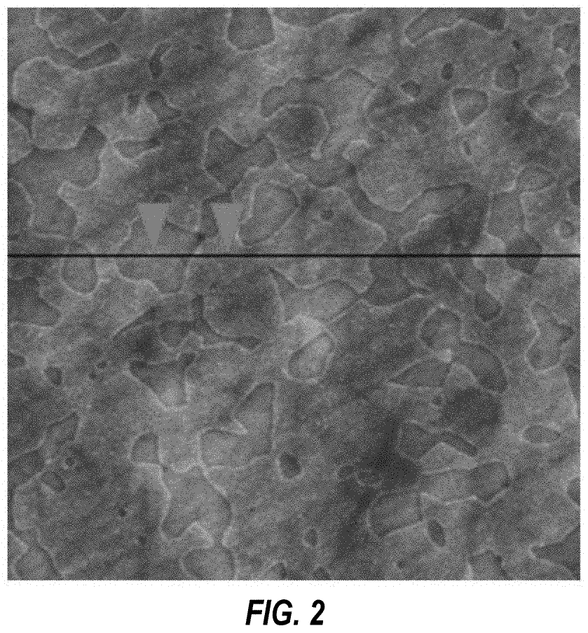

FIG. 2 is a magnified image of an AlTic surface showing example results after treating the AlTiC surface with the first particle beam and the second particle beam. Note that scratches are mostly removed and z-height differences have been largely normalized.

One embodiment herein includes a method for performing corrective processing of a substrate using a particle beam system. A workpiece (which can be a microelectronic workpiece or semiconductor substrate) is positioned in a beam apparatus. The beam apparatus is configured to treat a workpiece using a particle beam. The beam apparatus includes a vacuum chamber having a beam line for forming a particle beam and treating the workpiece with the particle beam. The beam line can include various components used to generate particles and direct those particles in a line or trajectory toward a target. The beam line can also include an opening or pathway or space through which the particle beam travels toward a target. The beam apparatus also has a scanner (scanner apparatus) configured to physically translate the workpiece through the particle beam. The beam apparatus can be a GCIB tool described subsequently in more detail. The workpiece has a working surface to be corrected. Note that beam generation systems are generally known and various configurations of components are available for assembling a beam line and beam system.

The workpiece can be comprised of several layers having a top layer (working surface) to be corrected, or the workpiece can be comprised of a single material. The working surface includes scratches to be removed as well as mesas as high points and valleys as low points. The scratches having been formed as a result of polishing via CMP. The working surface is non-homogeneous in that the working surface has composition differences that vary spatially across the working surface. This can be an alloy including AlTiC. For example, this can be an alloy without perfect homogeneity. Prior to positioning the workpiece in the beam apparatus, the working surface is non-planar in that that there are relative z-height differences greater than a predetermined amount. For some applications, if a surface is specified to have 0.0 nm height differences, then a given surface is non planar if having relative z-height differences greater than 1 nm. The workpiece can be planarized via CMP prior to being positioned in the beam apparatus.

A first particle beam is generated in the vacuum chamber. The first particle beam being a particle beam of inert particles. For example, a feed gas of nitrogen or argon is processed as a gas cluster ion beam. The workpiece is then scanned through the first particle beam according to a first correction map for a first characteristic of a working surface of the workpiece. The correction map can identify coordinate locations of the scratches. The first particle beam causes a modification of the first characteristic on the working surface of the workpiece. In other words, a given workpiece can be measured to identify locations of high spots, low spots and scratches to be corrected. The workpiece is then moved through the beam based on the correction map. Dwell time and beam intensity for any given point location on the workpiece can be adjusted. This particle beam treatment reduces a value of the scratches and increases a smoothness value of the working surface. This value can be a measure of the scratches that represents any of length, width, height, and/or amount of scratches to objectively characterize or measure the scratches. This first particle beam can function to etch valleys on the workpiece preferential to mesas. The first particle beam thus increases a smoothness value of the working surface.

A second particle beam is generated in the vacuum chamber. The second particle beam is a particle beam of reactive particles, such as with a gas cluster ion beam. For example, feed gases can be selected from, but not limited to, NF₃, CF₄, CHF₃, SiF₄, SF₆, or any other halogenated gas. The workpiece is scanned through the second particle beam according to a second correction map for a second characteristic of the working surface of the workpiece. In one embodiment, each workpiece can be measured to generate correction maps. The first and second correction maps can be complimentary or identical depending on type and location of non-uniformity to correct. Correction maps can also be generated by lot of wafer or substrates for repeating patterns. The second particle beam causes a modification of the second characteristic on the working surface of the workpiece.

The second characteristic of the working surface can include a roughness value, wherein the second correction map identifies coordinate locations of z-height differences. The second particle beam then bombards the working surface reducing a roughness value of the working surface. The second particle beam can preferentially etch mesas on the working surface as compared to valleys. The second beam can then modify the working surface of the workpiece by reducing an average step height value across the working surface.

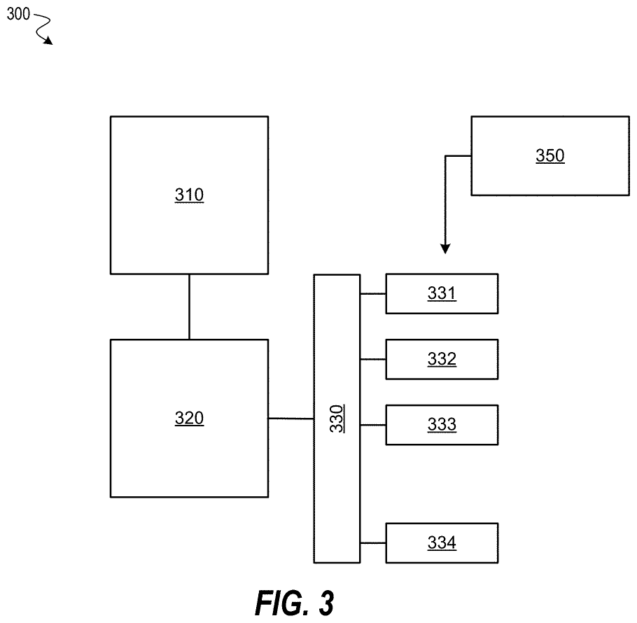

Turning now to FIG. 3, a processing system 300 can be configured to perform corrective processing on a microelectronic workpiece. The processing system 300 can include a corrective processing system 310 configured to treat a microelectronic workpiece with one or more corrective processes. A multi-process controller 320 includes data interface 330 programmably configured to receive a first set of parametric data from a first source 331 that diagnostically relates to at least a first portion of a microelectronic workpiece. Data interface 330 can optionally receive a second set of parametric data from a second source 332, which can be different than the first source 331 that diagnostically relates to at least a second portion of the microelectronic workpiece. A corrective process and/or correction map can be generated and then a target region of the workpiece is processed by applying the corrective process to the target region using a combination of the first set of parametric data and the optional second set of parametric data. The multi-process controller 320 may also interface with additional data sources 333, 334. For example, some data sources can provide correction data applicable to a lot of wafers, while other correction data applies to one specific wafer after measurement.

Processing system 300 can include a spatial modulation system configured to spatially modulate an applied property of the corrective process, based at least in part on the first and second sets of parametric data, as a function of position on the workpiece to achieve a target profile of a workpiece attribute. Furthermore, processing system 300 can include a metrology system 350 configured to collect at least the first set of parametric data for one or more workpieces.

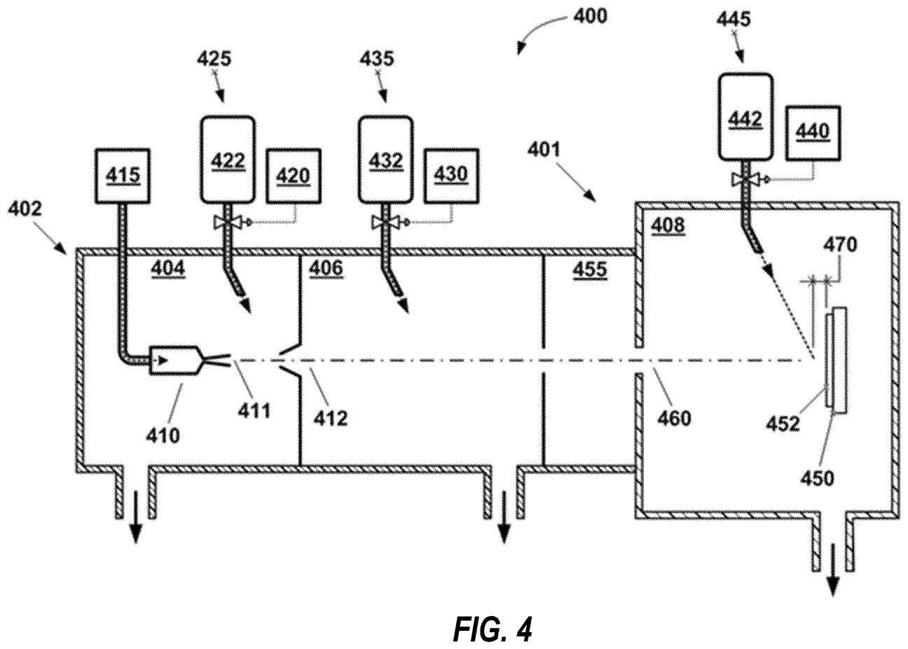

According to one embodiment, the corrective processing system 310 includes a beam processing system. Referring now to FIG. 4, a gas cluster ion beam (GCIB) processing system 400 is described according to an embodiment. In particular, GCIB processing system 400 includes a GCIB source 401 having a nozzle assembly 410 that is configured to introduce a primary gas from a process gas supply system 415 through the nozzle assembly 410 to a vacuum vessel 402 in order to produce a gas cluster beam. An ionizer 412 is positioned downstream from the nozzle assembly 410, and configured to ionize the gas cluster beam to produce a GCIB.

The GCIB processing system 400 further includes a workpiece holder 450, upon which a workpiece 452 to be processed is affixed and scanned within vacuum vessel 402. Vacuum vessel 402 comprises three communicating chambers, namely, a source chamber 404, an ionization/acceleration chamber 406, and a processing chamber 408 to provide a reduced-pressure enclosure. The three chambers are evacuated to suitable operating pressures by one or more vacuum pumping systems. In the three communicating chambers 404, 406, 408, a gas cluster beam can be formed in the first chamber (source chamber 404), while a GCIB can be formed in the second chamber (ionization/acceleration chamber 406) wherein the gas cluster beam is ionized and accelerated. Then, in the third chamber (processing chamber 408), the accelerated GCIB may be used to treat workpiece 452. The vacuum vessel 402 may also include a pressure cell chamber 455. The pressure cell chamber 455 is coupled to an inert gas supply system (not shown in FIG. 4) that supplies a background gas to the pressure cell chamber 455 for elevating the pressure in the pressure cell chamber 455.

The GCIB processing system 400 can further include a secondary gas source (425, 435, 445), wherein the secondary gas source (425, 435, 445) includes a secondary gas supply system (422, 432, 442) that delivers a secondary gas, and a secondary gas controller (420, 430, 440) that operatively controls the flow of the secondary gas injected into the GCIB processing system 400 downstream of the nozzle assembly 410. In one embodiment, the secondary gas source 425 is arranged to deliver the secondary gas into the source chamber 404 downstream of the exit 411 of the nozzle assembly 410. In another embodiment, the secondary gas source 435 is arranged to deliver the secondary gas into the ionization/acceleration chamber 406 downstream of a ionizer 412. In another embodiment, the secondary gas source 445 is arranged to deliver the secondary gas into the processing chamber 408 downstream of a final aperture 460. In another embodiment, any combination of the secondary gas source (425, 435, 445) may be used.

In another embodiment, the secondary gas source 445 is arranged to deliver the secondary gas into the processing chamber 408 downstream of the final aperture 460 and along a path that intersects the GCIB at a location spaced away from the exposed surface of workpiece 452 by a separation distance 470 (for example, the secondary gas is directed to the processing chamber 408 at or near an impact region of the GCIB with the substrate). Separation distance 470 may be a distance less than 10 mm, less than 5 mm, less than 2 mm, or substantially nil (the secondary gas may be a jet or beam that intersects the GCIB at the exposed surface of the substrate).

The secondary gas controller (420, 430, 440) may be coupled to one or more flow control valves, flow sensors, or pressure sensors. And, the secondary gas controller (420, 430, 440) can control a pressure (e.g., total/stagnation pressure) at which the secondary gas is injected, or a flow rate of the secondary gas, or combination thereof.

Additional details concerning the design of a gas cluster ion beam system are provided in U.S. Patent Application Publication No. 2010/0193701A1, entitled “Multiple Nozzle Gas Cluster Ion Beam System” and filed on Apr. 23, 2009; and U.S. Patent Application Publication No. 2010/0193472A1, entitled “Multiple Nozzle Gas Cluster Ion Beam Processing System and Method of Operating” and filed on Mar. 26, 2010, the contents of which are herein incorporated by reference in their entirety.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

1. A method for performing corrective processing of a substrate, the method comprising:
positioning a workpiece in a beam apparatus, the beam apparatus configured to treat a workpiece using a particle beam, the beam apparatus including a vacuum chamber having a beam line configured to form a particle beam and treat the workpiece with the particle beam, and a scanner configured to translate the workpiece through the particle beam, the workpiece having a working surface to be corrected;
generating a first particle beam in the vacuum chamber, the first particle beam being a particle beam of inert particles;
scanning the workpiece through the first particle beam according to a first correction map for a first characteristic of a working surface of the workpiece, the first particle beam causing a modification of the first characteristic on the working surface of the workpiece;
generating a second particle beam in the vacuum chamber, the second particle beam being a particle beam of reactive particles; and
scanning the workpiece through the second particle beam according to a second correction map for a second characteristic of the working surface of the workpiece, the second particle beam causing a modification of the second characteristic on the working surface of the workpiece.

2. The method of claim 1, wherein the working surface of the workpiece includes scratches to be removed, the scratches formed from polishing the working surface of the workpiece via chemical-mechanical polishing.

3. The method of claim 1, wherein the first characteristic of the working surface of the workpiece includes scratches, wherein the first correction map identifies coordinate locations of the scratches on the working surface of the workpiece, wherein the first particle beam bombards the working surface reducing a value of the scratches.

4. The method of claim 3, wherein the first particle beam is formed as a gas cluster ion beam.

5. The method of claim 1, wherein the second characteristic of the working surface includes a roughness value, wherein the second correction map identifies coordinate locations of z-height differences on the working surface of the workpiece, wherein the second particle beam bombards the working surface sufficiently to cause a reduction in a roughness value of the working surface of the workpiece.

6. The method of claim 5, wherein the second particle beam is formed as a gas cluster ion beam.

7. The method of claim 5, wherein the second particle beam is formed from a gas selected from the group consisting of NF₃, CF₄, CHF₃, SiF₄, and SF₆.

8. The method of claim 1, wherein the working surface is comprised of AlTiC.

9. The method of claim 1, wherein the working surface is non-homogeneous in that the working surface has composition differences that vary spatially across the working surface of the workpiece.

10. The method of claim 1, wherein prior to positioning the workpiece in the beam apparatus, the working surface is non-planar in that that there are relative z-height differences greater than 1 nanometer.

11. The method of claim 1, wherein the workpiece is positioned in the beam apparatus after having been planarized via chemical-mechanical polishing, the chemical-mechanical polishing resulting in scratching of the working surface and the working surface being non-planar.

12. The method of claim 1, wherein the working surface to be corrected includes scratches and a topography having mesas as high points and valleys as low points.

13. The method of claim 12, wherein the first particle beam preferentially etches valleys on the working surface.

14. The method of claim 12, wherein the second particle beam preferentially etches mesas on the working surface of the workpiece.

15. The method of claim 1, wherein the first particle beam modifies the working surface of the workpiece by reducing scratches and increasing a smoothness value of the working surface.

16. The method of claim 1, wherein the second particle beam modifies the working surface of the workpiece by reducing an average step height value across the working surface.

17. A method for processing a workpiece with a particle beam, the method comprising:
positioning a workpiece on a scanner in a vacuum chamber configured to form a particle beam and treat the workpiece with the particle beam, the workpiece having a working surface comprising AlTiC, the working surface including scratches and having a roughness value that identifies a relative roughness of the working surface;
generating a first particle beam in the vacuum chamber, the first particle beam being a particle beam of inert particles;
scanning the workpiece through the first particle beam according to a correction map for a first characteristic of a working surface of the workpiece, the first particle beam causing a reduction in a value of scratches on the working surface;
generating a second particle beam in the vacuum chamber, the second particle beam being a particle beam of reactive particles; and
scanning the workpiece through the second particle beam, the second particle beam chemically etching the working surface at predetermined locations causing a reduction in the roughness value of the working surface.
